(19) United States
(12) Patent Application Publication
(10) Pub. No.: US 2026/0186481 A1
(43) Pub. Date: Jul. 2, 2026

(54) INFORMATION PROCESSING APPARATUS, SUBSTRATE PROCESSING APPARATUS, AND INFORMATION PROCESSING METHOD

(71) Applicant: Tokyo Electron Limited, Tokyo (JP)

(72) Inventors: Nobutoshi TERASAWA, Hokkaido (JP); Kenichi KOBAYASHI, Hokkaido (JP); Koichiro YAMAMOTO, Mie (JP)

(21) Appl. No.: 19/426,897

(22) Filed: Dec. 19, 2025

(30) Foreign Application Priority Data
Dec. 27, 2024 (JP) 2024-231973

(51) Int. Cl. G05B 23/02

(52) U.S. Cl. CPC G05B 23/0283

(57) ABSTRACT

An information processing apparatus includes: an information acquisition unit that acquires information on preventive maintenance management from a plurality of substrate processing apparatuses each having a preventive maintenance management function; a prediction unit that predicts a maintenance time for each of the plurality of substrate processing apparatuses based on the information on the preventive maintenance management; and a display control unit that displays a list of the maintenance time for the plurality of substrate processing apparatuses on an output device.

.

### CROSS REFERENCES TO RELATED APPLICATIONS

This application is based on and claims priority from Japanese Patent Application No. 2024-231973, filed on Dec. 27, 2024, with the Japan Patent Office, the disclosure of which is incorporated herein in its entirety by reference.

### TECHNICAL FIELD

The present disclosure relates to an information processing apparatus, a substrate processing apparatus, and an information processing method.

### BACKGROUND

In substrate processing apparatuses, for example, replacement of parts due to an end of life or an occurrence of failure is performed through maintenance. In prior art, a technique has been known, in which parts of a substrate processing apparatus that need to be replaced are detected in advance using a simulation model of the substrate processing apparatus (see, e.g., Japanese Patent No. 7556642).

### SUMMARY

According to an aspect of the present disclosure, an information processing apparatus includes: an information acquisition unit that acquires information on preventive maintenance management from a plurality of substrate processing apparatuses each having a preventive maintenance management function; a prediction unit that predicts a maintenance time for each of the plurality of substrate processing apparatuses based on the information on the preventive maintenance management; and a display control unit that displays a list of the maintenance time for the plurality of substrate processing apparatuses on an output device.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a substrate processing system according to an embodiment of the present disclosure.

FIG. 2 is a view illustrating an example of a hardware configuration of a computer.

FIG. 3 is a functional block diagram illustrating an example of an operator terminal according to an embodiment of the present disclosure.

FIG. 4 is a sequence diagram illustrating an example of a process in which the operator terminal according to an embodiment of the present disclosure displays a list of maintenance times for a plurality of substrate processing apparatuses.

FIG. 5 is an image view illustrating an example of a screen displaying a list of maintenance times for a plurality of substrate processing apparatuses.

FIG. 6 is an image view illustrating an example of a screen displaying a list of maintenance times for a plurality of substrate processing apparatuses.

FIG. 7 is a functional block diagram illustrating an example of an operator terminal according to an embodiment of the present disclosure.

FIG. 8 is a sequence diagram illustrating an example of a process in which an operator terminal according to an embodiment of the present disclosure displays a list of maintenance times for a plurality of substrate processing apparatuses.

FIG. 9 is an image view illustrating an example of a screen displaying a list of maintenance times for a plurality of substrate processing apparatuses.

FIG. 10 is a functional block diagram illustrating an example of an operator terminal according to an embodiment of the present disclosure.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment of the present embodiment will be described with reference to the drawings.

### First Embodiment

### (System Configuration)

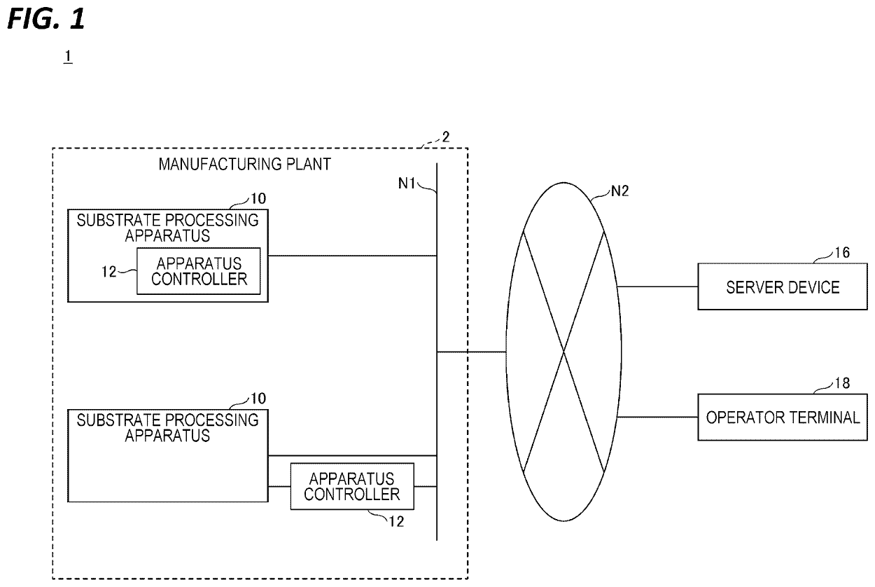

FIG. 1 is a view illustrating an example of a configuration of a substrate processing system 1 according to an embodiment of the present disclosure. As illustrated in FIG. 1, the substrate processing system 1 includes a substrate processing apparatus 10, an apparatus controller 12, a server device 16, and an operator terminal 18. The substrate processing system 1 includes a plurality of substrate processing apparatuses 10.

The substrate processing apparatus 10 and the apparatus controller 12 are provided in a manufacturing plant 2. The server device 16 and the operator terminal 18 may be provided in or outside the manufacturing plant 2. The operator terminal 18 is, for example, a personal computer (PC) or a smartphone operated by an operator such as a person in charge of performing the maintenance of the substrate processing apparatus 10 or a planner who plans the maintenance.

In FIG. 1, the substrate processing apparatus 10, the apparatus controller 12, the server device 16, and the operator terminal 18 are connected to each other for communication via networks N1 and N2 such as the Internet or a local area network (LAN).

The substrate processing apparatus 10 performs a processing such as film deposition, etching, or ashing, and processes substrates such as semiconductor wafers. The substrate processing apparatus 10 may be, for example, a semiconductor manufacturing apparatus, a heat treatment apparatus, or a film deposition apparatus. The substrate processing apparatus 10 may be a batch type apparatus or a single wafer type apparatus. Hereinafter, descriptions will be made on, for example, a case where the substrate processing apparatus 10 is a batch type film deposition apparatus.

The substrate processing apparatus 10 receives, for example, control commands (e.g., setting values) according to a recipe from the apparatus controller 12 to perform processes. The substrate processing apparatus 10 includes multiple types of sensors such as a temperature sensor, a pressure sensor, and a gas flow sensor, which are used to detect a fault or measure the apparatus state.

The substrate processing apparatus 10 has a preventive maintenance management function. The preventive maintenance management function outputs an alarm, for example, when film thickness, processing time, processing count, or the like which is accumulated through process execution, exceeds a threshold value. The operator may determine a maintenance time for the substrate processing apparatus 10 from the output of the alarm.

The substrate processing apparatus 10 may further include a fault detection/prediction management function and a parts management function. The fault detection/prediction management function monitors performance degradation over time based on information measured by the plurality of sensors provided in the substrate processing apparatus 10. The fault detection/prediction management function outputs an alarm when a fault is detected or predicted. The operator may determine a maintenance time for the substrate processing apparatus 10 from the output of the alarm. The parts management function monitors, for example, a timing for replacing parts of the substrate processing apparatus 10. The parts management function outputs an alarm when, for example, film thickness, processing time, processing count, or operation count of parts, which is accumulated through process execution, exceeds a threshold value. The operator may determine a maintenance time for the substrate processing apparatus 10 from the output of the alarm.

The apparatus controller 12 receives instructions for the substrate processing apparatus 10 from the operator. The apparatus controller 12 has a man-machine interface function to provide the operator with information on the substrate processing apparatus 10. The apparatus controller 12 outputs an alarm to the operator. The apparatus controller 12 records information on the preventive maintenance management, information on the fault detection/prediction management, and information on the parts management in a storage unit provided inside or outside the apparatus. Details of the information on the preventive maintenance management, the information on the fault detection/prediction management, and the information on the parts management will be described herein later. The apparatus controller 12 may provide the information on the preventive maintenance management, the information on the fault detection/prediction management, and the information on the parts management to the server device 16 or the operator terminal 18.

While FIG. 1 illustrates the apparatus controller 12 provided for each substrate processing apparatus 10, the apparatus controller 12 may be provided for the plurality of substrate processing apparatuses 10. The apparatus controller 12 may be provided inside or outside a housing of the substrate processing apparatus 10.

The server device 16 or the operator terminal 18 may receive the information on the preventive maintenance management, the information on the fault detection/prediction management, and the information on the parts management from the plurality of substrate processing apparatuses 10 in one or more manufacturing plants 2, and may record the received information in the storage unit.

The apparatus controller 12, the server device 16, or the operator terminal 19 displays a list of maintenance times for the plurality of substrate processing apparatuses 10 as described herein later. The apparatus controller 12, the server device 16, or the operator terminal 18 may notify the operator of the maintenance times for the plurality of substrate processing apparatuses 10, using, for example, a mail function or a chat function. The server device 16 and the operator terminal 18 may have a man-machine interface function to display the information on the substrate processing apparatus 10, thereby notifying the information to the operator.

The apparatus controller 12, the server device 16, and the operator terminal 18 are each an example of an information processing apparatus according to the present embodiment. The substrate processing system 1 illustrated in FIG. 1 is merely an example, and various examples of system configuration may be conceived according to applications or purposes. The device classification illustrated in FIG. 1 such as the apparatus controller 12, the server device 16, and the operator terminal 18 is an example. Various configurations may be conceived such as a configuration where at least two of the apparatus controller 12, the server device 16, and the operator terminal 18 of the substrate processing system 1 illustrated in FIG. 1 are integrated, or a configuration where the devices are further divided.

### (Hardware Configuration)

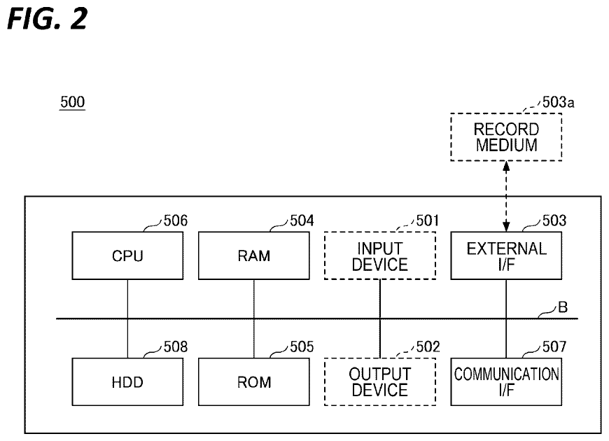

The apparatus controller 12, the server device 16, and the operator terminal 18 illustrated in FIG. 1 may be implemented by, for example, a computer having the hardware configuration illustrated in FIG. 2. FIG. 2 is a view illustrating an example of a hardware configuration of a computer 500.

The computer 500 of FIG. 2 includes, for example, an input device 501, an output device 502, an external I/F 503, a random access memory (RAM) 504, a read only memory (ROM) 505, a central processing unit (CPU) 506, a communication I/F 507, and a hard disk drive (HDD) 508, which are connected to each other via a bus B. The input device 501 and the output device 502 may be connected and used as needed.

The input device 501 is, for example, a keyboard, a mouse, or a touch panel, and is used by, for example, the operator to input operation signals. The output device 502 is, for example, a display, and displays results of processes executed by the computer 500. The communication I/F 507 is an interface that connects the computer 500 to the networks N1 and N2 illustrated in FIG. 1. The HDD 508 is an example of a nonvolatile storage device that stores programs and data. The CPU 506 is an example of a processor, and may include devices such as a graphics processing unit (GPU).

The external I/F 503 is an interface with external devices. The computer 500 may execute read of a record medium 503a, such as a secure digital (SD) memory card, through the external I/F 503. The computer 500 may execute record on the record medium 503a, such as a secure digital (SD) memory card, through the external I/F 503.

The ROM 505 is an example of a nonvolatile semiconductor memory (storage device) that stores programs and data. The RAM 504 is an example of a nonvolatile semiconductor memory (storage device) that temporarily holds programs and data. The CPU 506 is a calculation device that reads programs and data from the storage device such as the ROM 505 or the HDD 508 onto the RAM 504, and executes processes to implement the control and functions of the entire computer 500.

The apparatus controller 12, the server device 16, and the operator terminal 18 of the substrate processing system 1 illustrated in FIG. 1 execute programs by the computer 500 illustrated in FIG. 2, thereby implementing various functions.

### (Maintenance Time Determination by Operator)

In the manufacturing plant 2 illustrated in FIG. 1, the plurality of substrate processing apparatuses 10 are provided. The preventive maintenance management function outputs an alarm, for example, when film thickness, processing time, processing count or the like, which is accumulated through process execution, exceeds a threshold value. The operator may determine a maintenance time for the substrate processing apparatus 10 from the output of the alarm. However, when a large number of substrate processing apparatuses 10 are provided in the manufacturing plant 2, multiple substrate processing apparatuses 10 may require the maintenance simultaneously. In the case where multiple substrate processing apparatuses 10 require the maintenance simultaneously, downtime may increase due to shortage of operators.

The substrate processing apparatus 10 includes a plurality of maintenance items. Thus, it has been difficult to predict the maintenance times of the plurality of substrate processing apparatuses 10 installed in the manufacturing plant 2. Further, when the plurality of substrate processing apparatuses 10, which are performing the same process, are subjected to the maintenance simultaneously, the production capacity in the process may temporarily decline.

The present embodiment provides, for example, a function to predict a time at which the threshold value is reached, from an increasing trend of a cumulative value of film thickness, processing time, processing count or the like that is accumulated through process execution, and displays a list of maintenance times for the plurality of substrate processing apparatuses 10 on the output device 502. The operator may view the maintenance times for the plurality of substrate processing apparatuses 10 that are displayed in a list on the output device 502, thereby grasping the maintenance times for the plurality of substrate processing apparatuses 10 collectively. Further, since the operator may easily grasp overlap of the maintenance times among the plurality of substrate processing apparatuses 10, the operator may adjust the maintenance times to reduce the downtime of the plurality of substrate processing apparatuses 10, thereby optimizing the maintenance times.

### (Functional Configuration)

Hereinafter, descriptions will be made assuming an example where the information processing apparatus, which displays the list of maintenance times for the plurality of substrate processing apparatuses 10 on the output device 502, is the operator terminal 18. The information processing apparatus, which displays the list of maintenance times for the plurality of substrate processing apparatuses 10 on the output device 502, may be the apparatus controller 12 or the server device 16.

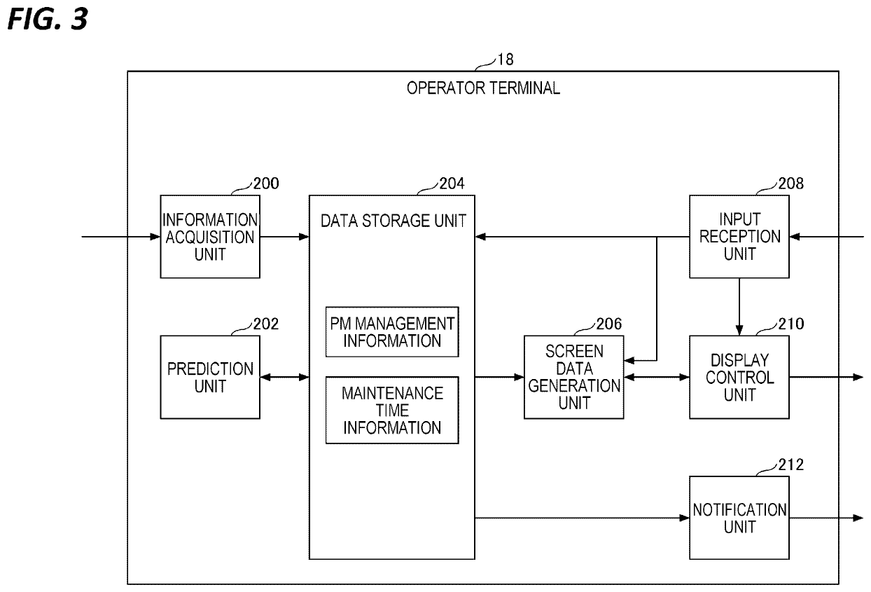

The operator terminal 18 of the substrate processing system 1 according to the present embodiment is implemented by, for example, functional blocks illustrated in FIG. 3. FIG. 3 is a functional block diagram illustrating an example of the operator terminal 18 according to the present embodiment. The functional block diagram of FIG. 3 omits the illustration of components unnecessary for the description of the present embodiment.

By executing a program for the operator terminal 18, the operator terminal 18 of FIG. 3 implements an information acquisition unit 200, a prediction unit 202, a data storage unit 204, a screen data generation unit 206, an input reception unit 208, a display control unit 210, and a notification unit 212.

The information acquisition unit 200 acquires information on the preventive maintenance management from the plurality of substrate processing apparatuses 10 each having the preventive maintenance management function. Hereinafter, the information on the preventive maintenance management will be referred to as PM management information. The information acquisition unit 200 may acquire the PM management information from the apparatus controller 12 or the server device 16. The information acquisition unit 200 records the acquired PM management information in the data storage unit 204.

The prediction unit 202 predicts a maintenance time for each of the plurality of substrate processing apparatuses 10 based on the PM management information. For example, the prediction unit 202 predicts the time at which the threshold value is reached for each of the plurality of substrate processing apparatuses 10, from the increasing trend of the cumulative value of the film thickness, processing time, processing count or the like that is accumulated through process execution. The operator may determine the predicted time at which the threshold value is reached, to be the maintenance time of each substrate processing apparatus 10. Further, the prediction unit 202 may predict the maintenance time for each of the plurality of substrate processing apparatuses 10 and each maintenance item, based on the PM management information.

The input reception unit 208 receives various operations from the operator. Examples of the operations received from the operator include an application startup operation and various operations on the started application. The input reception unit 208 notifies the contents of the various operations received from the operator to the screen data generation unit 206 and the display control unit 210. Further, the input reception unit 208 may receive addition of a maintenance item of which maintenance time has been designated, from the operator. The operator may manually add a maintenance item such as a periodic maintenance item that does not require the prediction of maintenance times.

The screen data generation unit 206 reads out maintenance time information recorded in the data storage unit 204, based on the contents of the various operations received from the operator. The screen data generation unit 206 generates screen data for a screen to be described herein later, such as a screen that displays the list of maintenance times for the plurality of substrate processing apparatuses 10, and transmits the generated screen data to the display control unit 210. The screen data generation unit 206 may generate screen data for a screen that displays the list of maintenance times for each of the plurality of substrate processing apparatuses 10 and each maintenance item, and transmit the generated screen data to the display control unit 210.

The display control unit 210 causes the output device 502 to display the screen to be described herein later, such as the screen that displays the list of maintenance times for the plurality of substrate processing apparatuses 10, according to the screen data received from the screen data generation unit 206 and the contents of the various operations of the operator notified from the input reception unit 208. The display control unit 210 may cause the output device 502 to display the screen that displays the list of maintenance times for each of the plurality of substrate processing apparatuses 10 and each maintenance item, according to the screen data received from the screen data generation unit 206 and the contents of the various operations of the operator notified from the input reception unit 208.

The notification unit 212 reads out the maintenance time information recorded in the data storage unit 204, and notifies the operator of the maintenance times for the plurality of substrate processing apparatuses 10 by using, for example, an email function or a chat function. The notification unit 212 may notify the operator of the maintenance times for the plurality of substrate processing apparatuses 10 by using a man-machine interface function.

### (Process)

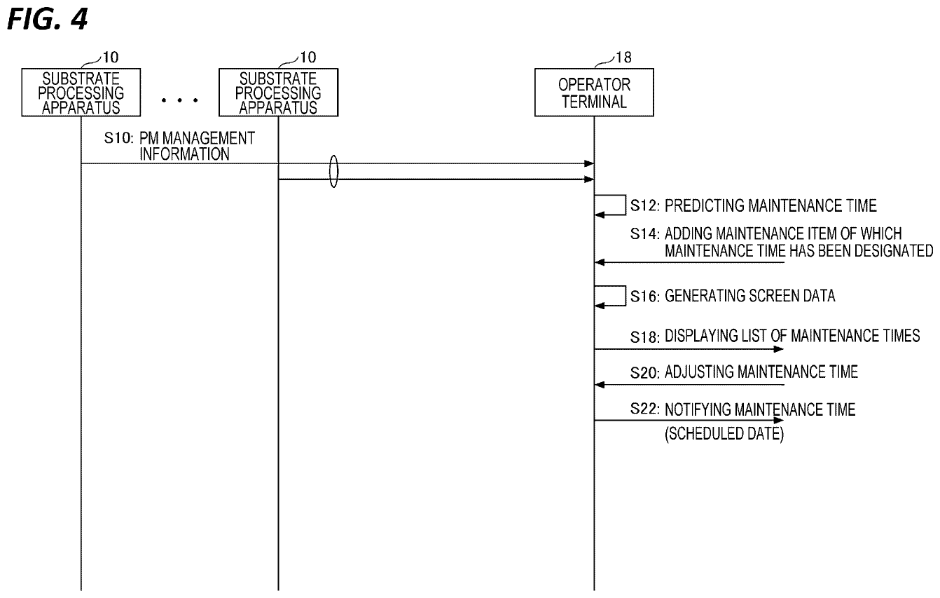

FIG. 4 is a sequence diagram illustrating an example of a process in which the operator terminal 18 according to the present embodiment displays the list of maintenance times for the plurality of substrate processing apparatuses 10.

In step S10, the information acquisition unit 200 of the operator terminal 18 acquires the PM management information from the plurality of substrate processing apparatuses 10. Further, the information acquisition unit 200 records the acquired PM management information for the plurality of substrate processing apparatuses 10 in the data storage unit 204. The process of step S10 may be performed at predetermined time intervals (e.g., every week), or at the timing when the prediction unit 202 predicts the maintenance times for the plurality of substrate processing apparatuses 10.

In step S12, the prediction unit 202 of the operator terminal 18 predicts the maintenance time for each of the plurality of substrate processing apparatuses 10 based on the PM management information stored in the data storage unit 204. The prediction unit 202 predicts the time at which the threshold value is reached for each of the plurality of substrate processing apparatuses 10, from the increasing trend of the cumulative value of the film thickness, processing time, processing count or the like that is accumulated through process execution. The prediction unit 202 records the predicted time at which the threshold value is reached for each of the plurality of substrate processing apparatuses 10 as maintenance time information indicating the maintenance time for each substrate processing apparatus 10, in the data storage unit 204.

In step S14, the input reception unit 208 of the operator terminal 18 receives, from the operator, addition of a maintenance item of which maintenance time has been designated, such as a maintenance item of periodic maintenance that does not require the prediction of maintenance times. The process of step S14 is skipped when the addition of a maintenance item of which maintenance time has been designated is unnecessary.

In step S16, the screen data generation unit 206 of the operator terminal 18 reads out the maintenance time information recorded in the data storage unit 204, and generates the screen data for the screen that displays the list of maintenance times for the plurality of substrate processing apparatuses 10.

In step S18, the display control unit 210 of the operator terminal 18 causes the output device 502 to display the screen that displays the list of maintenance times for the plurality of substrate processing apparatuses 10, according to the screen data generated by the screen data generation unit 206.

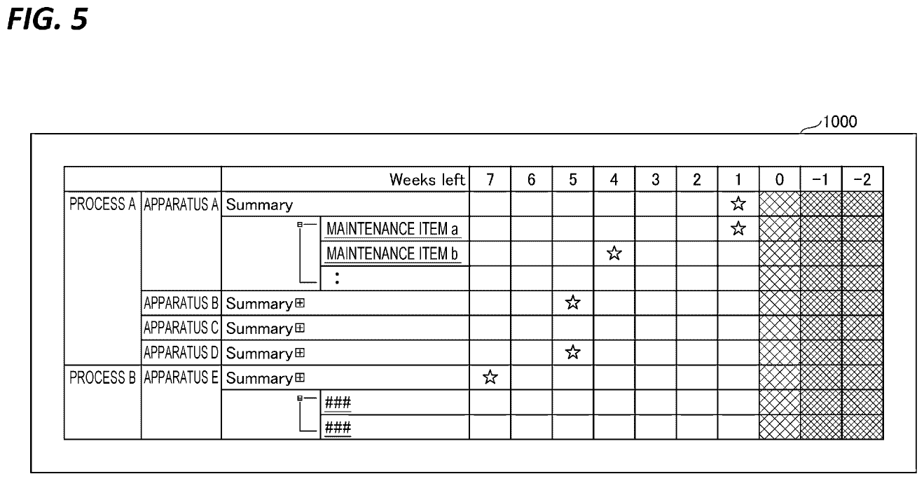

FIG. 5 is an image view illustrating an example of a screen 1000 displaying the list of maintenance times for the plurality of substrate processing apparatuses 10.

The screen 1000 visualizes the maintenance times for the plurality of substrate processing apparatuses 10, which are predicted by the prediction unit 202. The screen 1000 represents remaining time periods until the predicted maintenance times in units of weeks horizontally, for each of the plurality of substrate processing apparatuses 10 and each maintenance item. The position of the symbol “★” in the screen 1000 indicates a remaining time period until a predicted maintenance time for each of the plurality of substrate processing apparatuses 10 and each maintenance item.

For example, the screen 1000 represents that in the substrate processing apparatus 10 corresponding to “Apparatus A,” the remaining time period until the predicted maintenance time is “1 week.” Further, for example, the screen 1000 represents that in the substrate processing apparatus 10 corresponding to “Apparatus B,” the remaining time period until the predicted maintenance time is “5 weeks.” In the screen 1000, the position of the symbol “★” moves to the right side as time elapses. Weeks left “0” in the screen 1000 indicates the predicted time at which the threshold value is reached for each of the plurality of substrate processing apparatuses 10 and each maintenance item, based on the increasing trend of the cumulative value of the film thickness, processing time, processing count or the like that is accumulated through process execution.

The screen 1000 may switch between “Summary” display, which displays a remaining time period until a maintenance time for each of the plurality of substrate processing apparatuses 10, and “Maintenance Item” display, which displays remaining time periods until maintenance times for each of the plurality of substrate processing apparatuses 10 and each maintenance item.

The “Summary” display represents, for example, a remaining time period until the earliest maintenance time among the predicted maintenance times for respective maintenance items of a specific substrate processing apparatus 10, or a remaining time period until a maintenance time of a representative maintenance item of the specific substrate processing apparatus 10.

The “Maintenance Item” display represents, for example, a remaining time period until a predicted maintenance time for each maintenance item of a specific substrate processing apparatus 10, for each maintenance item. For example, the screen 1000 of FIG. 5 represents that in the substrate processing apparatus 10 corresponding to “Apparatus A,” the remaining time period until the maintenance time of a maintenance item “a” is “1 week,” and the remaining time period until the maintenance time of a maintenance item “b” is “4 weeks.”

By viewing the screen 1000 of FIG. 5, the operator may grasp that the maintenance times for the maintenance items “a” and “b” of the substrate processing apparatus 10 corresponding to “Apparatus A” are approaching, and may adjust the maintenance times of the maintenance items “a” and “b” to perform the maintenance on both items. Therefore, the operator may optimize the maintenance times to reduce the downtime of the substrate processing apparatus 10.

Further, by viewing the screen 1000 of FIG. 5, the operator may easily grasp overlap of the maintenance times between the substrate processing apparatuses 10 corresponding to “Apparatus B” and “Apparatus D.” Thus, for example, the operator may make an adjustment to advance the maintenance time of the substrate processing apparatus 10 corresponding to “Apparatus B” by “2 weeks,” thereby avoiding the overlap of the maintenance times between the plurality of substrate processing apparatuses 10, and optimizing the maintenance times.

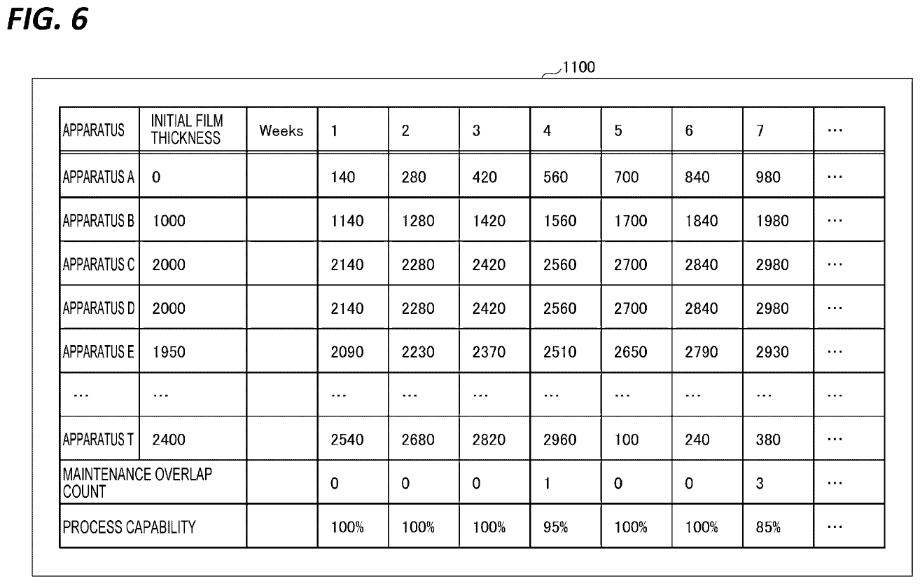

The screen 1000 of FIG. 5 is merely an example, and a screen 1100 of FIG. 6 may be implemented. FIG. 6 is an image view illustrating an example of the screen 1100 displaying the list of maintenance times for the plurality of substrate processing apparatuses 10. The screen 1100 of FIG. 6 represents the predicted time at which the threshold value is reached for each of the plurality of substrate processing apparatuses 10, based on the increasing trend of the cumulative value of the film thickness accumulated through process execution. FIG. 6 illustrates an example in which the threshold value of the cumulative value of the film thickness is “2,900 nm.” Further, FIG. 6 illustrates an example in which the film thickness increases by “5 nm” through one process execution, and four process executions are performed per day. For example, in the screen 1100 of FIG. 6, the cumulative value of the film thickness that exceeds the threshold value may be visually distinguished by, for example, color, highlighting, shading, or an enclosing line, such that the operator may easily identify the cumulative value.

The screen 1100 represents the cumulative value of the film thickness accumulated through process execution in units of weeks horizontally for each of the plurality of substrate processing apparatuses 10. The “Maintenance Overlap Count” in the screen 1100 represents the number of overlaps of the maintenance times in units of weeks. For example, the “Maintenance Overlap Count” of the screen 1100 of FIG. 6 represents that the maintenance times of three substrate processing apparatuses 10 overlap in Weeks “7.”

By referring to the “Maintenance Overlap Count” of the screen 1100, the operator may easily grasp the week when the maintenance times overlap. For example, when two substrate processing apparatuses 10 may be subjected to the maintenance in one week, the operator may easily make an adjustment on Weeks “7” in which the maintenance times of the three substrate processing apparatuses 10 overlap, for example, by advancing the maintenance time of one of the three substrate processing apparatuses 10 by one week. The “Maintenance Overlap Count” of the screen 1100 is an example of information on the overlap of the maintenance times.

The “Process Capability” of the screen 1100 indicates the weekly process capability of the plurality of substrate processing apparatuses 10, assuming that when all the substrate processing apparatuses 10 are performing a process, the process capability is 100%, and a substrate processing apparatus 10 is not performing a process during its maintenance time.

Accordingly, for example, the operator may adjust the maintenance times of the plurality of substrate processing apparatuses 10 to ensure that the “Maintenance Overlap Count” of the screen 1100 does not exceed the number of substrate processing apparatuses 10 that may be subjected to the maintenance in one week, thereby optimizing the maintenance times.

Returning to step S20 of FIG. 4, the operator adjusts the maintenance times by inputting and saving a scheduled maintenance date with reference to the screen 1000 or 1100 displayed on the output device 502.

In step S22, the notification unit 212 notifies the operator of the maintenance times (the scheduled maintenance date) based on the maintenance time information recorded in the data storage unit 204. The notification in step S22 may be performed when the scheduled maintenance date approaches, for example, a predetermined number of days before the scheduled maintenance date, thereby prompting the operator to prepare for the maintenance.

### Second Embodiment

Since the second embodiment is similar to the first embodiment, except for specific components, descriptions thereof will be omitted as appropriate.

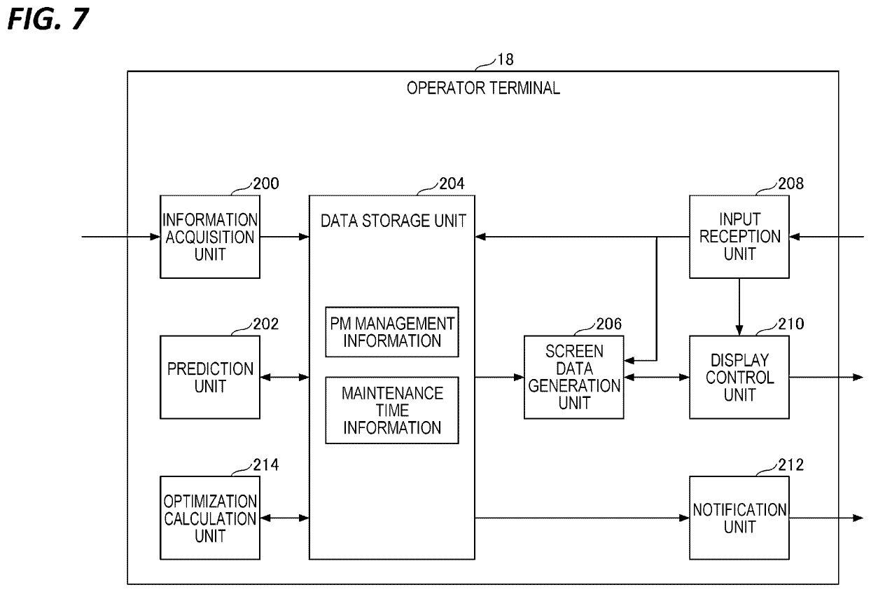

FIG. 7 is a functional block diagram illustrating an example of an operator terminal 18 according to the present embodiment. The functional block diagram of FIG. 7 represents a configuration where an optimization calculation unit 214 is added to the functional block diagram illustrated in FIG. 3.

The optimization calculation unit 214 optimizes the maintenance times for each of the plurality of substrate processing apparatuses 10 and each maintenance item, which are predicted by the prediction unit 202, to reduce the downtime of the plurality of substrate processing apparatuses 10.

For example, the optimization calculation unit 214 adjusts the maintenance times for the plurality of substrate processing apparatuses 10 to avoid the overlap of the maintenance times of the plurality of substrate processing apparatuses 10, thereby optimizing the maintenance times to be proposed to the operator. Further, the optimization calculation unit 214 adjusts the approaching maintenance times of the maintenance items in the same substrate processing apparatus 10 to perform the maintenance on both items, thereby optimizing the maintenance times to be proposed to the operator.

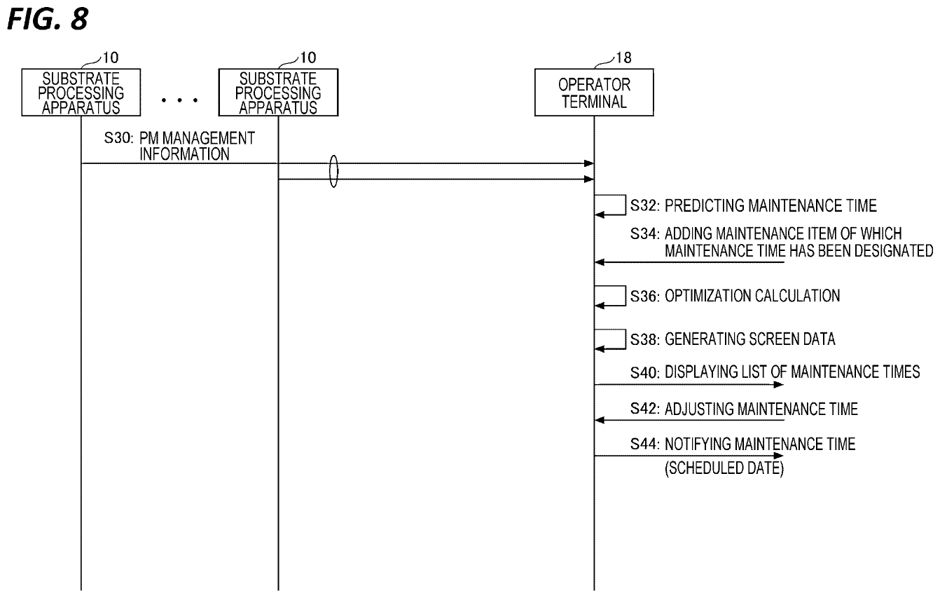

FIG. 8 is a sequence diagram illustrating an example of a process in which the operator terminal 18 according to the present embodiment displays the list of maintenance times for the plurality of substrate processing apparatuses 10. Since the sequence diagram of FIG. 8 is similar to the sequence diagram of FIG. 4, except for specific steps, descriptions thereof will be omitted as appropriate.

Since the processes of steps S30 to S34 are similar to those of steps S10 to S14 of FIG. 4, descriptions thereof will be omitted.

In step S36, the optimization calculation unit 214 of the operator terminal 18 reads out the maintenance time information recorded in the data storage unit 204. The optimization calculation unit 214 optimizes the maintenance times for the plurality of substrate processing apparatuses 10 and the maintenance items, which will be proposed to the operator, to reduce the downtime of the plurality of substrate processing apparatuses 10. The optimized maintenance times are added to the maintenance time information recorded in the data storage unit 204.

In step S38, the screen data generation unit 206 of the operator terminal 18 reads out the maintenance time information recorded in the data storage unit 204, and generates screen data for a screen that displays the list of maintenance times for the plurality of substrate processing apparatuses 10.

In step S40, the display control unit 210 of the operator terminal 18 causes the output device 502 to display the screen that displays the list of maintenance times for the plurality of substrate processing apparatuses 10, based on the screen data generated by the screen data generation unit 206.

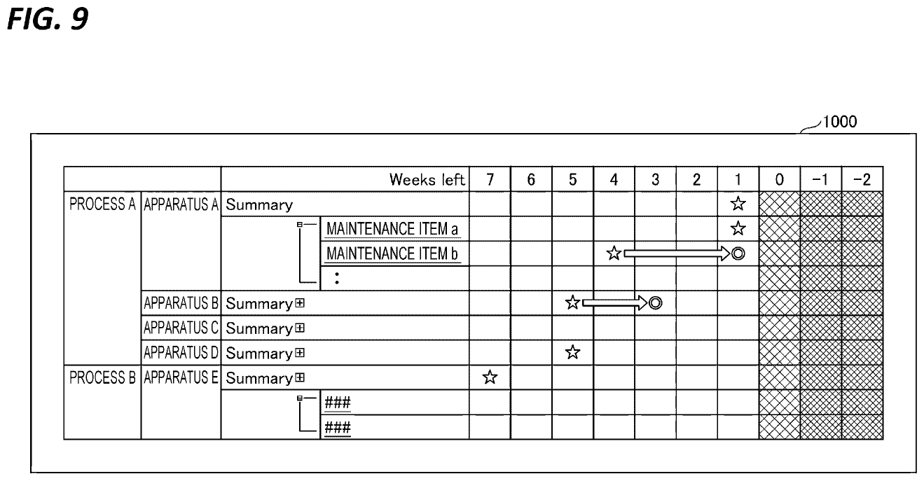

FIG. 9 is an image view illustrating an example of a screen 1000 displaying the list of maintenance times for the plurality of substrate processing apparatuses 10. Since the screen 1000 of FIG. 9 is similar to the screen 1000 of FIG. 5, except for specific parts, descriptions thereof will be omitted as appropriate.

The screen 1000 visualizes the maintenance times predicted by the prediction unit 202 for the plurality of substrate processing apparatuses 10, and the proposal of the maintenance times optimized by the optimization calculation unit 214 for the plurality of substrate processing apparatuses 10 and the maintenance items.

The screen 1000 displays remaining time periods until the predicted maintenance times in units of weeks horizontally for each of the plurality of substrate processing apparatuses 10 and each maintenance item. The position of the symbol “☆” in the screen 1000 indicates a remaining time period until a predicted maintenance time for each of the plurality of substrate processing apparatuses 10 and each maintenance item.

The position of the symbol “⊚” in the screen 1000 indicates the proposal of the maintenance time optimized by the optimization calculation unit 214 for the plurality of substrate processing apparatuses 10 and the maintenance items.

For example, in the screen 1000 of FIG. 9, the maintenance times of the substrate processing apparatuses 10 corresponding to “Apparatus B” and “Apparatus D” overlap. The screen 1000 of FIG. 9 proposes an optimized maintenance time by displaying the symbol “⊚” at a position advanced by “two weeks” from the position of “☆” indicating the maintenance time of the substrate processing apparatus 10 corresponding to “Apparatus B.”

For example, in order to coordinate the maintenance times of the maintenance items “a” and “b” of the substrate processing apparatus 10 corresponding to “Apparatus A” and perform the maintenance on both items, the screen 1000 of FIG. 9 proposes an optimized maintenance time by displaying the symbol “⊚” at a position advanced by “three weeks” from the position of “☆” indicating the maintenance time of the maintenance item “b” of the substrate processing apparatus 10.

Therefore, by viewing the screen 1000 of FIG. 9, the operator may easily grasp the contents of the optimization of the maintenance times that reduce the downtime of the substrate processing apparatuses 10.

Returning to step S42 of FIG. 8, the operator adjusts the maintenance times by inputting and saving a scheduled maintenance date with reference to the screen 1000 displayed on the output device 502.

In step S44, the notification unit 212 notifies the operator of the maintenance times (e.g., the scheduled maintenance date) based on the maintenance time information recorded in the data storage unit 204. The notification in step S44 may be performed when the scheduled maintenance date approach, for example, a predetermined number of days before the scheduled maintenance date, thereby prompting the operator to prepare for the maintenance.

The optimization of the maintenance times by the optimization calculation unit 214 in step S36 may be performed through machine learning such as deep learning using a machine learning model that has learned maintenance items requiring the maintenance in the same time period. For example, the machine learning model learns estimated maintenance work time, work preparation categories, and information on whether to perform the maintenance in the same time period, for each maintenance item. The work preparation categories include, for example, increasing/decreasing the temperature of a processing chamber of the substrate processing apparatus 10, opening a loading area, and stopping a pump.

In the second embodiment, descriptions have been made on an example where the optimized maintenance times are proposed to the operator. However, the maintenance times predicted by the prediction unit 202 for the plurality of substrate processing apparatuses 10 and the maintenance items may be updated to the maintenance times optimized by the optimization calculation unit 214.

### Third Embodiment

Since the third embodiment is similar to the first or second embodiment except for specific components, descriptions thereof will be omitted as appropriate.

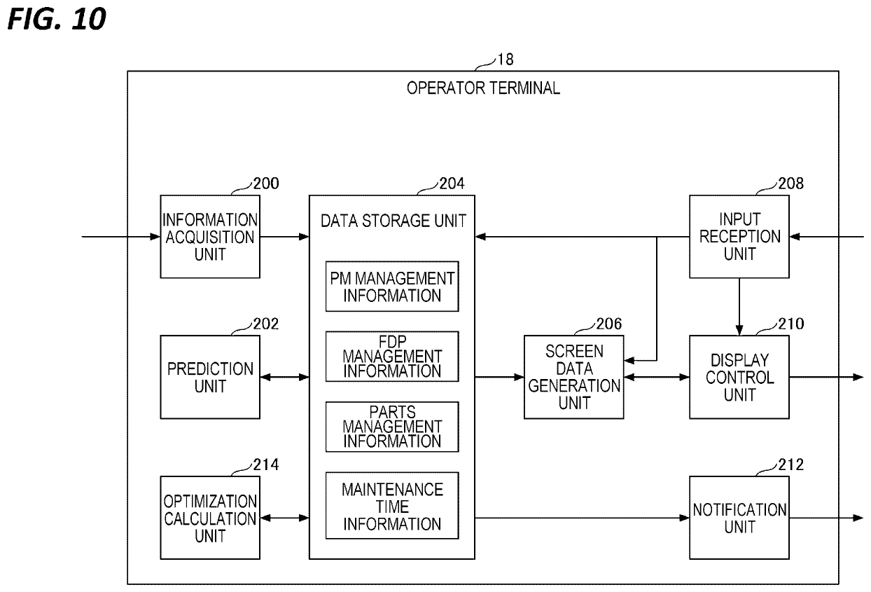

FIG. 10 is a functional block diagram illustrating an example of an operator terminal 18 according to the present embodiment. The functional block diagram of FIG. 10 is different from the functional block diagram illustrated in FIG. 7 in terms of the data recorded in the data storage unit 204.

The information acquisition unit 200 further acquires information on fault detection/prediction management and information on parts management from the substrate processing apparatus 10 having a fault detection/prediction management function and a parts management function. Hereinafter, the information on fault detection/prediction management will be referred to as FDP management information. Further, the information acquisition unit 200 may acquire the PM management information, the FDP management information, and the parts management information from the apparatus controller 12 or the server device 16. The information acquisition unit 200 records the acquired PM management information, FDP management information, and parts management information in the data storage unit 204.

The prediction unit 202 predicts a maintenance time for each of the plurality of substrate processing apparatuses 10 based on the PM management information, the FDP management information, and the parts management information. The prediction unit 202 predicts not only a time at which a cumulative value of the PM management information reaches a threshold value, but also a time at which a measurement value of the FDP management information reaches a threshold value, and a time at which the parts management information reaches a recommended replacement time (e.g., a threshold value). The operator may determine the reaching time, which is predicted based on the PM management information, the FDP management information, and the parts management information, to be the maintenance time for each maintenance item of the substrate processing apparatus 10.

When the maintenance time optimization process by the optimization calculation unit 214 is performed using machine learning, a machine learning model is used, which has been machine-learned to output the following output data in response to the following input data.

The input data include, for example, a maintenance prediction execution date, estimated work time for each maintenance item, work preparation categories, user set parameters, and selection of a key maintenance item.

The maintenance prediction execution date is, for example, a predicted value of the time at which the cumulative value of the PM management information reaches the threshold value. The time at which the cumulative value of the PM management information reaches the threshold value is, for example, a predicted value of a time at which the number of times of process executions reaches 1,000.

The maintenance prediction execution date is also, for example, a predicted value of the time at which the parts management information reaches the recommended replacement time (e.g., a threshold value). The recommended replacement time of the parts management information may be set as time elapsed from start of operation of parts, or may be set as the number of times parts operate.

Further, the maintenance prediction execution date is, for example, a predicted value of the time at which the measurement value of the FDP management information reaches the threshold value. The time at which the measurement value of the FDP management information reaches the threshold value is, for example, a predicted value of a time at which the measurement value reaches a monitoring band (e.g., a threshold value), through a function of monitoring performance degradation over time based on measurement values obtained from the plurality of sensors provided in the substrate processing apparatuses 10.

The estimated work time for each maintenance item is work time required for the maintenance of the maintenance item (e.g., estimated time for work performed by the operator).

In the work preparation categories, preparation tasks are set in advance, which are necessary to perform the maintenance and require a relatively long time, such as increasing/decreasing the temperature of the processing chamber of the substrate processing apparatus 10, opening the loading area, or stopping the pump. A work preparation category may be selected for each maintenance item.

The user set parameters are, for example, apparatus group setting, the allowable number of apparatuses of which maintenance times overlap, and fixed item setting. The apparatus group setting sets the scope (e.g., a range) of the substrate processing apparatuses 10 for which the optimization calculation of maintenance times is performed. For example, the apparatus group setting sets six of ten substrate processing apparatuses 10 (e.g., apparatuses 1 to 6) as Group A, and the remaining four apparatuses (e.g., apparatuses 7 to 10) as Group B.

The allowable number of apparatuses of which maintenance times overlap sets the maximum allowable number of apparatuses of which maintenance times overlap, within the same group. For example, the allowable number of apparatuses of which maintenance times overlap sets maximum three substrate processing apparatuses 10 of which maintenance times overlap in Group A, and maximum two substrate processing apparatuses 10 of which maintenance times overlap in Group B. The fixed item setting sets a maintenance item of which maintenance time is strictly observed, as a fixed item of which maintenance time is not changeable.

The selection of a key maintenance item may set one maintenance item of a specific substrate processing apparatus 10. When a maintenance item of a specific substrate processing apparatus 10 is set by the selection of a key maintenance item, the optimization calculation unit 214 performs the optimization calculation of the maintenance times of the other substrate processing apparatuses 10 and maintenance items, by taking the selected maintenance item of the specific substrate processing apparatus 10 as a reference.

The output data is, for example, an optimal maintenance time (e.g., maintenance execution date) for each maintenance item of the plurality of substrate processing apparatuses 10. The output data may include a recommendation score based on the downtime of the plurality of substrate processing apparatuses 10 that may be reduced by performing the maintenance at the optimal maintenance time. The screen 1000 of FIG. 9 may visualize the recommendation score included in the output data for each optimized maintenance time to be proposed to the operator.

According to the substrate processing system 1 of the present disclosure, it is possible to provide a technology, which supports the optimization of maintenance times for the plurality of substrate processing apparatuses 10.

Each substrate processing apparatus 10 of the present disclosure may be applied to any type of apparatuses including an Atomic Layer Deposition (ALD) apparatus, Capacitively Coupled Plasma (CCP), Inductively Coupled Plasma (ICP), Radial Line Slot Antenna (RLSA), Electron Cyclotron Resonance Plasma (ECR), and Helicon Wave Plasma (HWP). The substrate processing apparatus 10 of the present disclosure may also be applied to a chemical vapor deposition (CVD) apparatus and an oxidation/annealing apparatus.

The substrate processing system 1 of the present disclosure is not limited to the configuration illustrated in FIG. 1, and various examples of system configuration may be conceived according to applications and purposes. The substrate processing apparatus 10 of the present disclosure may be applied to any of a sheet type substrate processing apparatus that processes substrates one by one, a batch type substrate processing apparatus that processes multiple substrates collectively, and a semi-batch type substrate processing apparatus. The processes performed by the substrate processing apparatus 10 of the present disclosure may be, for example, film deposition or etching.

According to the present disclosure, it is possible to provide a technology, which supports the optimization of maintenance times for a plurality of substrate processing apparatuses.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
information acquisition circuitry configured to acquire information on preventive maintenance management from a plurality of substrate processing apparatuses each having a preventive maintenance management function;
prediction circuitry configured to predict a maintenance time for each of the plurality of substrate processing apparatuses based on the information on the preventive maintenance management; and
display control circuitry configured to display a list of the maintenance time for the plurality of substrate processing apparatuses on an output device.

2. The information processing apparatus according to claim 1, wherein the prediction circuitry predict the maintenance time for each of the plurality of substrate processing apparatuses and each maintenance item based on the information on the preventive maintenance management, and
the display control circuitry display the list of the maintenance time for each of the plurality of substrate processing apparatuses and each maintenance item on the output device.

3. The information processing apparatus according to claim 2, further comprising:
optimization calculation circuitry configured to optimize the maintenance time predicted by the prediction circuitry for each of the plurality of substrate processing apparatuses and each maintenance item, thereby reducing downtime of the plurality of substrate processing apparatuses,
wherein the display control circuitry display the list of the maintenance time optimized by the optimization calculation circuitry on the output device.

4. The information processing apparatus according to claim 1, wherein the display control circuitry display information on overlap of the maintenance time.

5. The information processing apparatus according to claim 1, wherein the information acquisition circuitry further acquire information on fault detection/prediction management and information on parts management from the plurality of substrate processing apparatuses each further having a fault detection/prediction management function and a parts management function; and
the prediction circuitry predict the maintenance time for each of the plurality of substrate processing apparatuses based on the information on the preventive maintenance management, the information on the fault detection/prediction management, and the information on the parts management.

6. The information processing apparatus according to claim 2, further comprising:
input reception circuitry configured to receive, from an operator, addition of a maintenance item of which maintenance time has been designated.

7. The information processing apparatus according to claim 1, further comprising:
notification circuitry configured to notify an operator of the maintenance time of the plurality of substrate processing apparatuses.

8. A substrate processing apparatus comprising:
a memory; and
a processor coupled to the memory and configured to:
acquire information on preventive maintenance management from a plurality of substrate processing apparatuses each having a preventive maintenance management function;
predict a maintenance time for each of the plurality of substrate processing apparatuses based on the information on the preventive maintenance management; and
display a list of the maintenance time for the plurality of substrate processing apparatuses on an output device.

9. An information processing method performed by an information processing apparatus, the information processing method comprising:
acquiring information on preventive maintenance management from a plurality of substrate processing apparatuses each having a preventive maintenance management function;
predicting a maintenance time for each of the plurality of substrate processing apparatuses based on the information on the preventive maintenance management; and
displaying a list of the maintenance time for the plurality of substrate processing apparatuses on an output device.
